(19) United States
(12) Patent Application Publication
(10) Pub. No.: US 2026/0089927 A1
(43) Pub. Date: Mar. 26, 2026

(54) SEMICONDUCTOR STRUCTURE AND MANUFACTURING METHOD THEREOF

(71) Applicant: NANYA TECHNOLOGY CORPORATION, New Taipei City (TW)

(72) Inventor: Yu Hsuan LIANG, New Taipei City (TW)

(21) Appl. No.: 18/892,725

(22) Filed: Sep. 23, 2024

(51) Int. Cl. H10B 12/00

(52) U.S. Cl. CPC H10B 12/482

(57) ABSTRACT

A semiconductor structure is provided. The semiconductor structure includes a substrate, a bit line structure, a seed layer, a first spacer, a second spacer, a third spacer, and an air gap. The substrate has a recess, wherein the recess has a sharp corner. The bit line structure is on the substrate, wherein the recess surrounds the bit line structure. The seed layer is located on a sidewall of the bit line structure. The first spacer is located on a sidewall of the seed layer and on a bottom surface of the recess. The second spacer is filled in the recess. The third spacer is located on the substrate and adjacent to the first spacer. The air gap is between the first spacer and the third spacer; wherein a bottom of the air gap exposes a portion of a top surface of the second spacer.

### BACKGROUND

### FIELD OF INVENTION

The present disclosure relates to a semiconductor structure and manufacturing method thereof.

### DESCRIPTION OF RELATED ART

In recent decades, demand to storage capability has increased as electronic products continue to improve. In order to increase storage capability of a memory device (e.g., a DRAM device), more memory cells are integrated in the memory device. As the integration level increases, semiconductor structures may cause leakage issue.

### SUMMARY

In accordance with an aspect of the present disclosure, a manufacturing method of a semiconductor structure is provided. A bit line structure is provided on a substrate, wherein a recess surrounds the bit line structure. A seed layer is formed, wherein a first portion of the seed layer is on a top surface of the bit line structure, a second portion of the seed layer is on a sidewall of the bit line structure, and a third portion of the seed layer is on a bottom surface of the recess. The first portion of the seed layer and the third portion of the seed layer are removed, such that the second portion of the seed layer is remained on the sidewall of the bit line structure. A first spacer is formed on the top surface of the bit line structure, a sidewall of the second portion of the seed layer, and the bottom surface of the recess. A second spacer is formed to fill the recess. A sacrificial spacer is formed on the top surface of the bit line structure and a sidewall of the first spacer. A third spacer is formed on the sacrificial spacer. A portion of the third spacer and a portion of the sacrificial spacer to expose the top surface of the bit line structure. And a vapor etching process is performed to remove the sacrificial spacer, wherein an air gap is formed between the first spacer and the third spacer.

According to some embodiments of the present disclosure, wherein the first spacer and the third spacer are made by the same material.

According to some embodiments of the present disclosure, wherein the first spacer and the third spacer comprise nitride and hydrogen.

According to some embodiments of the present disclosure, wherein the first spacer, the second spacer and the third spacer comprise nitride.

According to some embodiments of the present disclosure, wherein the sacrificial spacer comprises oxide.

According to some embodiments of the present disclosure, wherein the seed layer comprises silicon.

According to some embodiments of the present disclosure, wherein a precursor for forming the seed layer comprising dichlorosilane (DCS).

According to some embodiments of the present disclosure, further including after the vapor etching process is performed, forming a poly silicon layer on the top surface of the substrate and forming a tungsten layer on the poly silicon layer and on the bit line structure, wherein the air gap is sealed by the tungsten layer.

According to some embodiments of the present disclosure, further including removing a portion of the tungsten layer to define a landing pad on the top surface of the bit line structure.

According to some embodiments of the present disclosure, further including after the portion of the tungsten layer is removed, forming an isolation layer on the tungsten layer.

In accordance with an aspect of the present disclosure, a semiconductor structure is provided. The semiconductor structure includes a substrate, a bit line structure, a seed layer, a first spacer, a second spacer, a third spacer, and an air gap. The substrate has a recess, wherein the recess has a sharp corner. The bit line structure is on the substrate, wherein the recess surrounds the bit line structure. The seed layer is located on a sidewall of the bit line structure. The first spacer is located on a sidewall of the seed layer and on a bottom surface of the recess. The second spacer is filled in the recess. The third spacer is located on the substrate and adjacent to the first spacer. The air gap is between the first spacer and the third spacer; wherein a bottom of the air gap exposes a portion of a top surface of the second spacer.

According to some embodiments of the present disclosure, wherein the bit line includes a first conductive layer, a second conductive layer, a first hard mask layer, and a second hard mask layer. The second conductive layer is on the first conductive layer. The first hard mask layer is on the second conductive layer. The second hard mask layer is on the first hard mask layer.

According to some embodiments of the present disclosure, further including a poly silicon layer and a tungsten layer. The poly silicon layer is on the substrate. The tungsten layer is on the poly silicon layer and over the top surface of the bit line structure, wherein the air gap is sealed by the tungsten layer.

According to some embodiments of the present disclosure, further including a landing pad and an isolation layer. The landing pad is on the top surface of the bit line structure. The isolation layer is on the tungsten layer, wherein the air gap is sealed by the isolation layer and the tungsten layer.

According to some embodiments of the present disclosure, wherein the top surface of the second spacer is coplanar with a top surface of the substrate.

According to some embodiments of the present disclosure, wherein the recess has a maximum depth near the bit line structure.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a cross-sectional view schematic diagram of a semiconductor structure, in accordance with some embodiments;

FIG. 2 is a cross-sectional view schematic diagram of a semiconductor structure after forming a seed layer, in accordance with some embodiments;

FIG. 3 is a cross-sectional view schematic diagram of a semiconductor structure after removing a portion of the seed layer, in accordance with some embodiments;

FIG. 4 is a cross-sectional view schematic diagram of a semiconductor structure after forming a first spacer, in accordance with some embodiments;

FIG. 5 is a cross-sectional view schematic diagram of a semiconductor structure after forming a second spacer, in accordance with some embodiments;

FIG. 6 is a cross-sectional view schematic diagram of a semiconductor structure after removing a portion of the second spacer, in accordance with some embodiments;

FIG. 7 is a cross-sectional view schematic diagram of a semiconductor structure after forming a sacrificial spacer, in accordance with some embodiments;

FIG. 8 is a cross-sectional view schematic diagram of a semiconductor structure after forming a third spacer, in accordance with some embodiments;

FIG. 9 is a cross-sectional view schematic diagram of a semiconductor structure after removing a portion of the third spacer and the sacrificial spacer, in accordance with some embodiments;

FIG. 10 is a cross-sectional view schematic diagram of a semiconductor structure after removing the sacrificial spacer, in accordance with some embodiments;

FIG. 11 is a cross-sectional view schematic diagram of a semiconductor structure after forming a poly silicon layer and a tungsten layer, in accordance with some embodiments; and

FIG. 12 is a cross-sectional view schematic diagram of a semiconductor structure after forming an isolation layer, in accordance with some embodiments.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

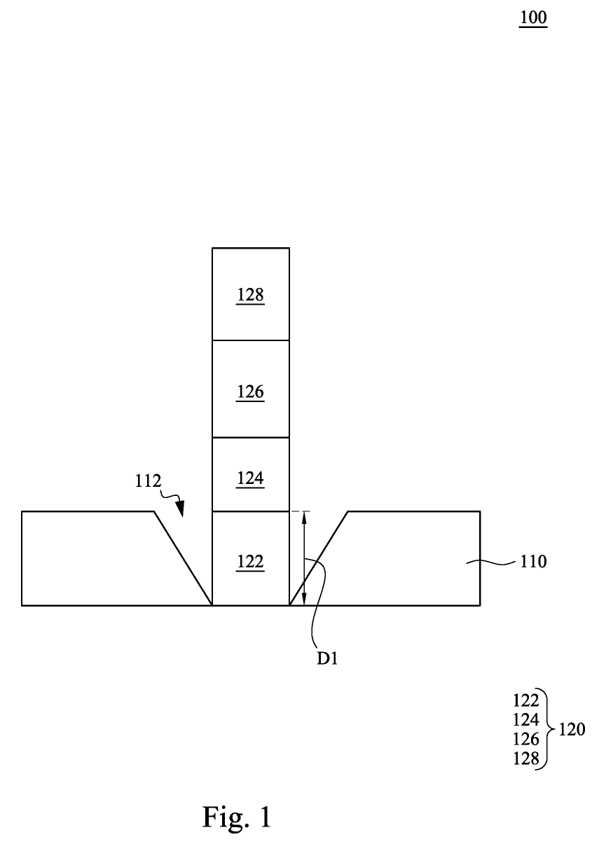

FIG. 1 to FIG. 12 are cross-sectional view schematic diagrams of various intermediate stages in the formation of a semiconductor structure 100, in accordance with some embodiments. The semiconductor structure 100 can be applied to or part of the integrated Circuit (IC), such as logic circuits, resistors, capacitors, sensors, memory device (such as dynamic random access memory (DRAM)). It should be understood that in order to simplify the graph, some components of the semiconductor structure 100 are not shown in FIG. 1 to FIG. 12, and other embodiments of the semiconductor structure 100 may include additional components.

In some embodiments, the substrate 110 may be a semiconductor substrate, such as a bulk semiconductor substrate, a semiconductor-on-insulator (SOI) substrate, etc., wherein the insulator may be a buried oxide (BOX) layer, a silicon oxide layer, or the like. In some embodiments, the substrate 110 can be doped (e.g., containing p-type or n-type dopants) or undoped. In some embodiments, the semiconductor material of the substrate 110 may include silicon, germanium, compound semiconductors (including silicon carbide, gallium arsenide, gallium phosphide, indium phosphide, indium arsenide, and/or indium antimonide), alloy semiconductors or a combination thereof. The substrate 110 can also be formed of other materials, such as sapphire, indium tin oxide, and the like.

As shown, the bit line structure 120 may include a first conductive layer 122, a second conductive layer 124, a first hard mask layer 126, and a second hard mask layer 128. The second conductive layer 124 is formed on the first conductive layer 122. The first hard mask layer 126 is formed on the second conductive layer 124. The second hard mask layer 128 is formed on the first hard mask layer 126. In some embodiments, the first conductive layer 122 and the second conductive layer 124 may include conductive material such as metal, metal alloy, metal nitride, or the like. For example, the first conductive layer 122 includes poly silicon. For example the second conductive layer 124 includes tungsten. In some embodiments, the first hard mask layer 126 and the second conductive layer 124 may include nitride, other dielectric materials or combinations thereof.

As shown in FIG. 1, the substrate 110 includes a recess 112. The recess 112 may be surrounding the bit line structure 120. In some embodiments, the recess 112 includes a sharp corner. In other words, the recess 112 has a maximum depth D1 near the bit line structure 120, and the depth of the recess 112 becomes smaller farther away from the bit line until it approaches zero. For example, the recess 112 has a vertical triangular cross-sectional profile. The recess 112 may be formed prior to forming the bit line structure 120, or the recess 112 may be formed subsequent to forming the bit line structure 120.

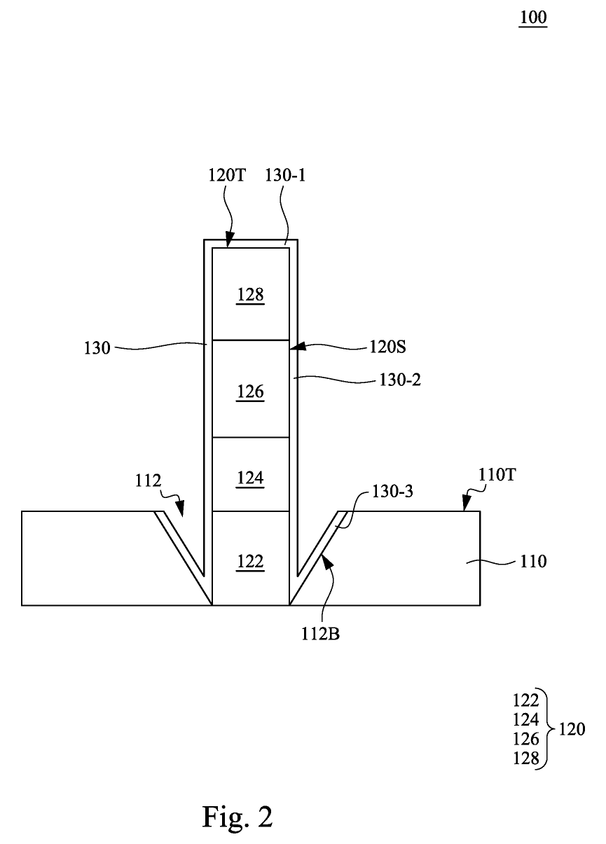

Referring to FIG. 2, a seed layer 130 is formed on the bit line structure 120 and in the recess 112. In detail, a first portion 130-1 of the seed layer 130 is formed over the top surface 120T and a second portion 130-2 of the sidewall 120S of the bit line structure 120, and a third portion 130-3 the seed layer 130 is formed on the bottom surface 112B of the recess 112. As shown in FIG. 2, the seed layer 130 is conformally formed on the bit line structure 120 and in the recess 112. In some embodiments, a precursor for forming the seed layer 130 includes dichlorosilane (DCS). In some embodiments, the seed layer 130 includes silicon. In some embodiments, the seed layer 130 may be formed using a suitable deposition process, such as chemical vapor deposition (CVD), plasma enhanced chemical vapor deposition (PECVD), atomic layer deposition (ALD), or the like.

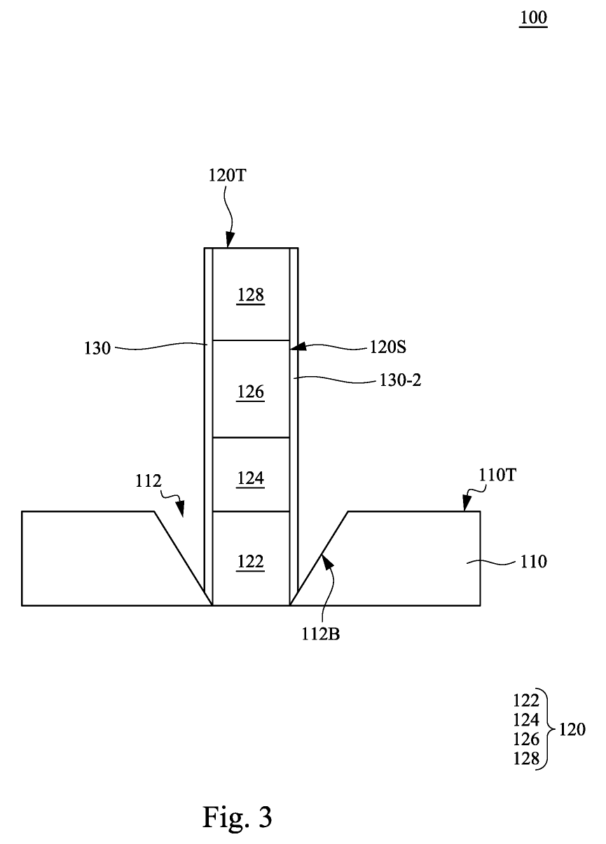

Referring to FIG. 3, a portion of the seed layer 130 is removed. In detail, the first portion 130-1 of the seed layer 130 on the top surface 120T of the bit line structure 120 is removed, and the third portion 130-3 of the seed layer 130 on the bottom surface 112B of the recess 112 is removed. The second portion 130-2 of the seed layer 130 is remained on the sidewall 120S of the bit line structure 120. The top surface 120T of the bit line structure 120 and the bottom surface 112B of the recess 112 are exposed. A portion of the seed layer 130 may be removed using a suitable directional dry etching process, such as plasma reactive etching, ion-beam etching, or the like.

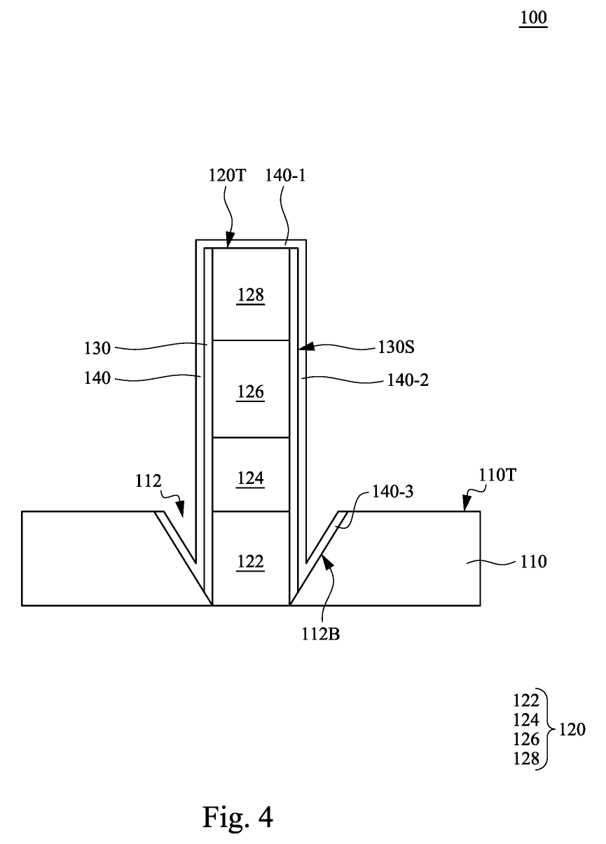

Referring to FIG. 4, a first spacer 140 is formed on the bit line structure 120 and the seed layer 130. In detail, a first portion 140-1 of the first spacer 140 is formed over the top surface 120T of the bit line structure 120, a second portion 140-2 of the sidewall 130S of the seed layer 130, and a third portion 140-3 on the bottom surface 112B of the recess 112. As shown in FIG. 4, the first spacer 140 is conformally formed over the bit line structure 120, on the seed layer 130, and in the recess 112. In some embodiments, a precursor for forming the first spacer 140 includes dichlorosilane (DCS), NH₃, and H₂. In some embodiments, the first spacer 140 includes nitride and hydrogen. In some embodiments, the first spacer 140 may be formed using a suitable deposition process, such as chemical vapor deposition (CVD), plasma enhanced chemical vapor deposition (PECVD), atomic layer deposition (ALD), or the like. The seed layer 130 may support the first spacer 140 nearing the bit line structure 120 to maintain the thickness uniformity of the first spacer 140 during the subsequent air gap formation process.

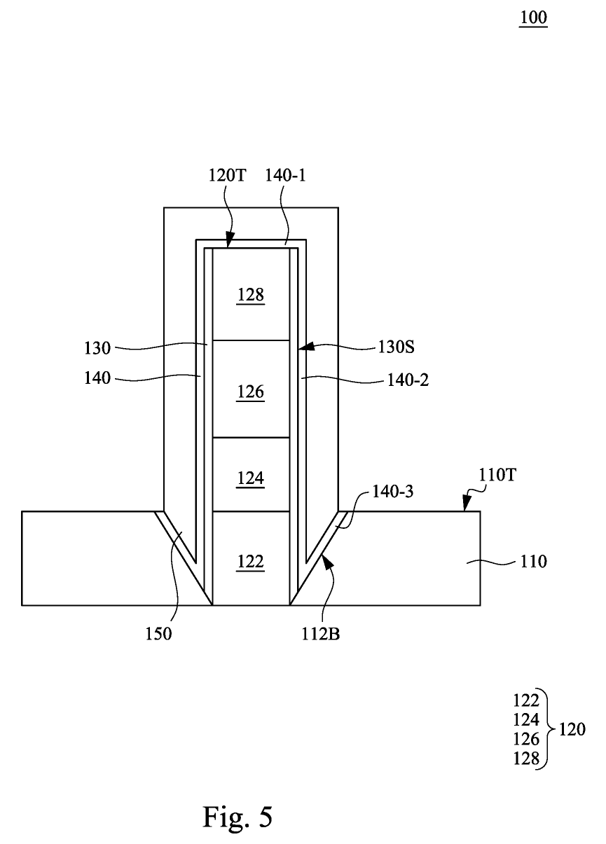

Referring to FIG. 5, a second spacer 150 is formed on the first spacer 140 and in the recess 112. In detail, the recess 112 is filled by the second spacer 150, and the first spacer 140 is covered by the second spacer 150. In some embodiments, a precursor for forming the second spacer 150 includes dichlorosilane (DCS) and NH_{3.} In some embodiments, the second spacer 150 includes nitride. In some embodiments, the first spacer 140 may be formed using a suitable deposition process, such as chemical vapor deposition (CVD), plasma enhanced chemical vapor deposition (PECVD), atomic layer deposition (ALD), or the like.

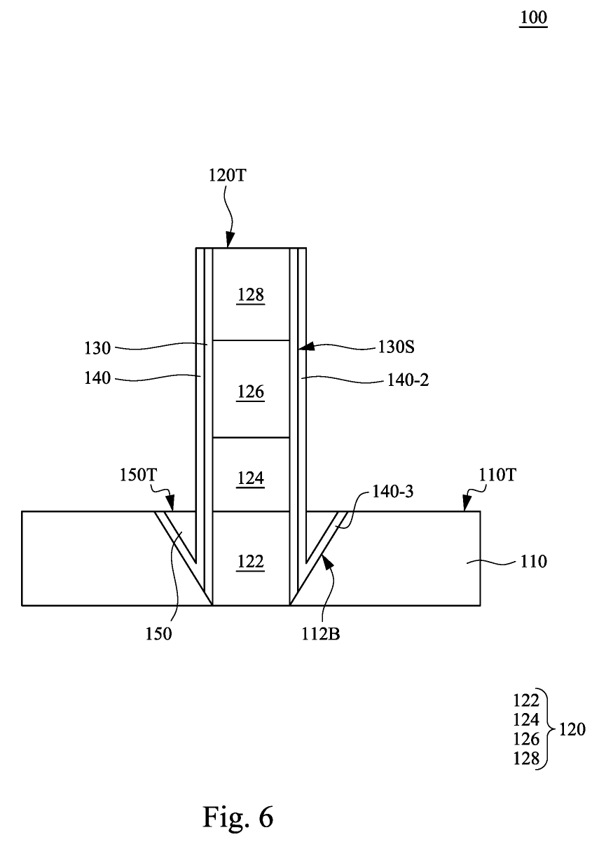

Referring to FIG. 6, a portion of the second spacer 150 is removed. The second spacer 150 that covers the first spacer 140 is removed. In other words, the second spacer 150 fills in the recess is remained. As shown in FIG. 6, after the removing process, the top surface 150T of the second spacer 150 can be coplanar with the top surface 110T of the substrate 110. In some embodiments, the first portion 140-1 of the first spacer 140 is removed to expose the top surface 120T of the bit line structure 120. The second portion 140-2 of the first spacer 140 is remained on the sidewall 130S of the seed layer 130. The portion of the second spacer 150 may be removed using a suitable directional dry etching process, such as plasma reactive etching, ion-beam etching, or the like. The second spacer 150 may support the first spacer 140 at the bottom to reduce collapse during the subsequent air gap formation process.

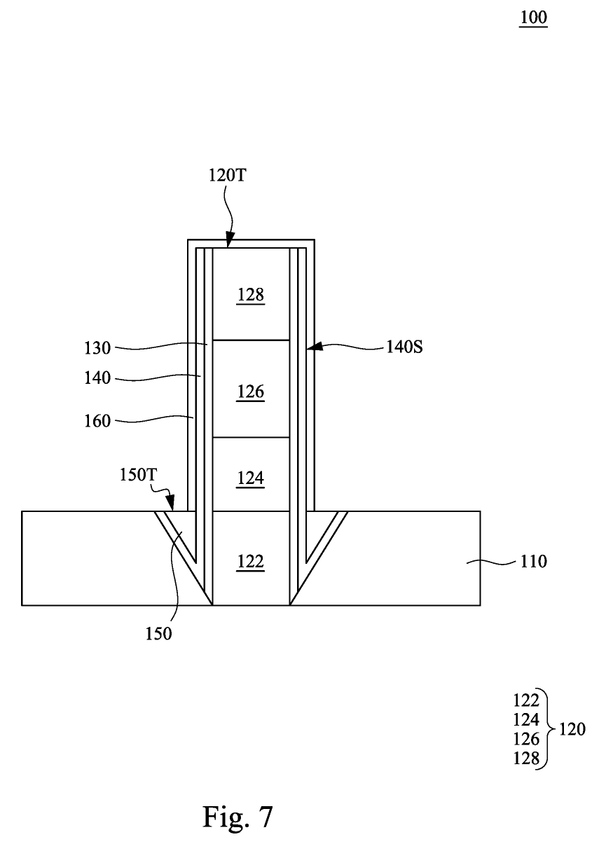

Referring to FIG. 7, a sacrificial spacer 160 is formed on the bit line structure 120. In detail, the sacrificial spacer 160 may be formed on the top surface 120T of the bit line structure 120, and the sacrificial spacer 160 may be formed on the sidewall 140S of the first spacer 140. As shown in FIG. 7, the sacrificial spacer 160 is conformally formed over the bit line structure 120 and on the first spacer 140. In some embodiments, the sacrificial spacer 160 includes oxide. In some embodiments, the sacrificial spacer 160 may be formed using a suitable deposition process, such as chemical vapor deposition (CVD), plasma enhanced chemical vapor deposition (PECVD), atomic layer deposition (ALD), or the like.

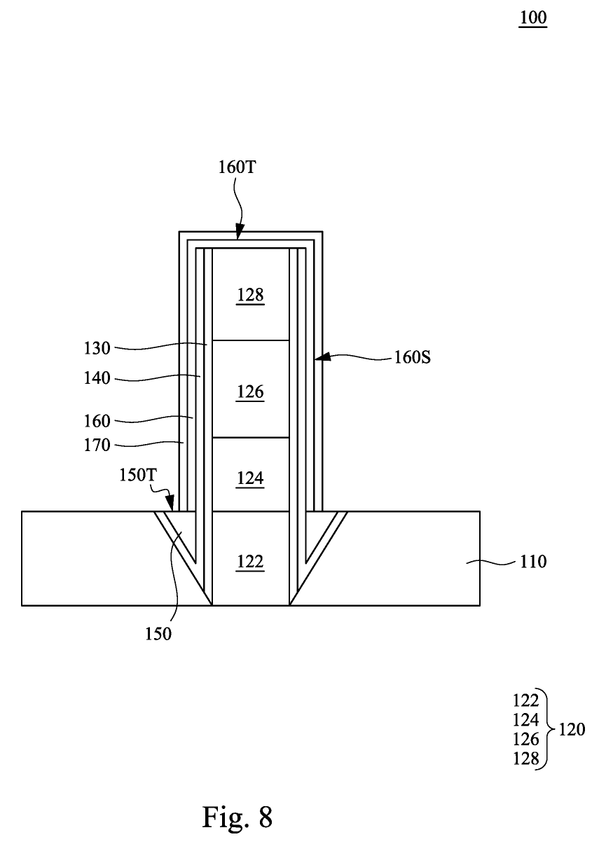

Referring to FIG. 8, a third spacer 170 is formed on the bit line structure 120. In detail, the third spacer 170 may be formed on the top surface 160T of the sacrificial spacer 160, and the third spacer 170 may be formed on the sidewall 160S of the sacrificial spacer 160. As shown in FIG. 8, the third spacer 170 is conformally formed over the sacrificial spacer 160. In some embodiments, a precursor for forming the third spacer 170 includes dichlorosilane (DCS), NH₃, and H₂. In some embodiments, the third spacer 170 includes nitride and hydrogen. In some embodiments, the third spacer 170 may be formed using a suitable deposition process, such as chemical vapor deposition (CVD), plasma enhanced chemical vapor deposition (PECVD), atomic layer deposition (ALD), or the like. In some embodiments, the third spacer 170 and the first spacer are made of the same material.

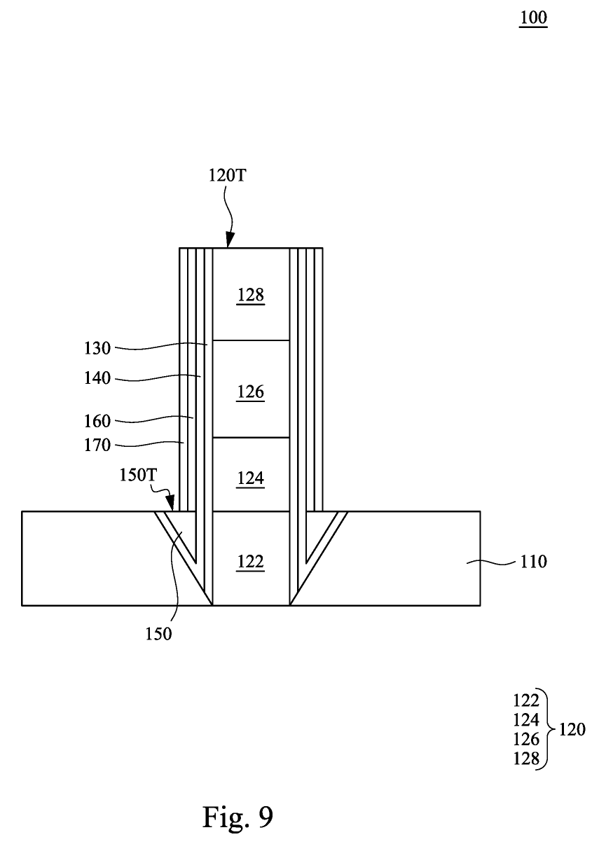

Referring to FIG. 9, a portion of the third spacer 170 and a portion of the sacrificial spacer 160 are removed. In detail, the top surface 120T of the bit line structure 120 is exposed after the removing process. The portion of the third spacer 170 and the portion of the sacrificial spacer 160 may be removed using a suitable directional dry etching process, such as plasma reactive etching, ion-beam etching, or the like.

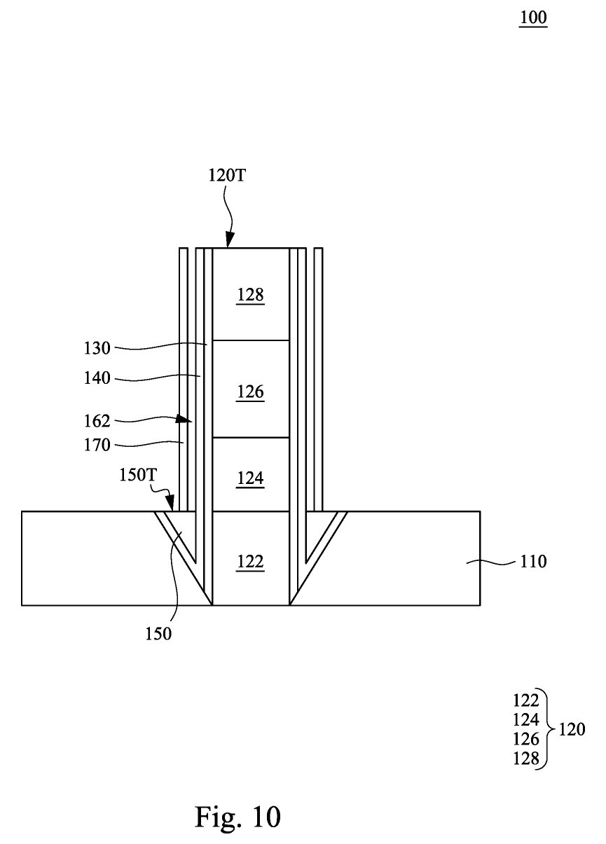

Referring to FIG. 10, the sacrificial spacer 160 is removed to form an air gap 162. After removing the sacrificial spacer 160, a portion of the top surface 150T of the second spacer 150 is exposed in the air gap 162. In some embodiments, the sacrificial spacer 160 is removed by a vapor etching process. The sacrificial spacer 160 which includes oxide has an etch selectivity with respect to the first spacer 140 and the third spacer 170. In other words, the etching rate on the sacrificial spacer 160 is higher than that on the first spacer 140 and the third spacer 170. The vapor etching process may selectively etch the sacrificial spacer 160 without harming the first spacer 140, to maintain the thickness uniformity of first spacer 140 and reduce leakage issue.

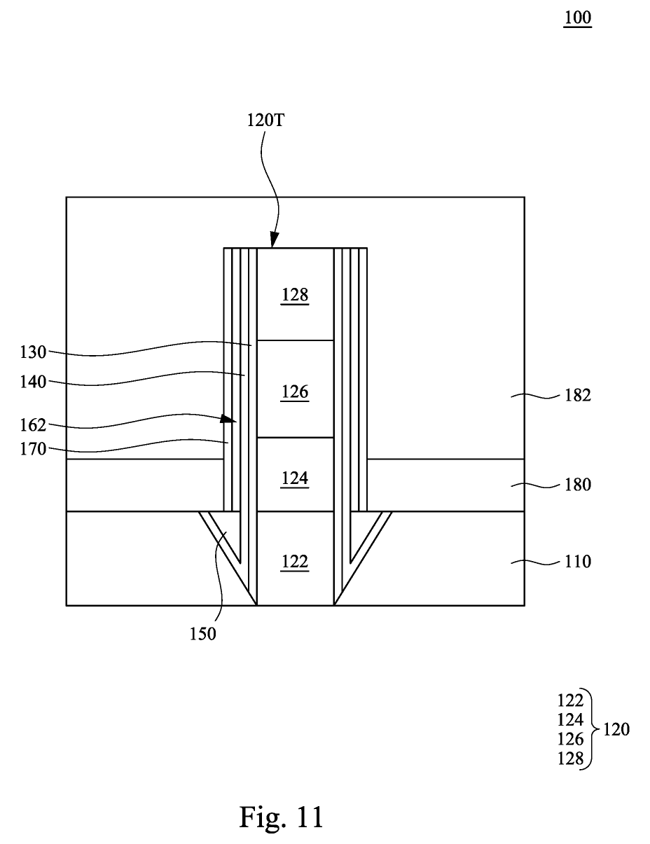

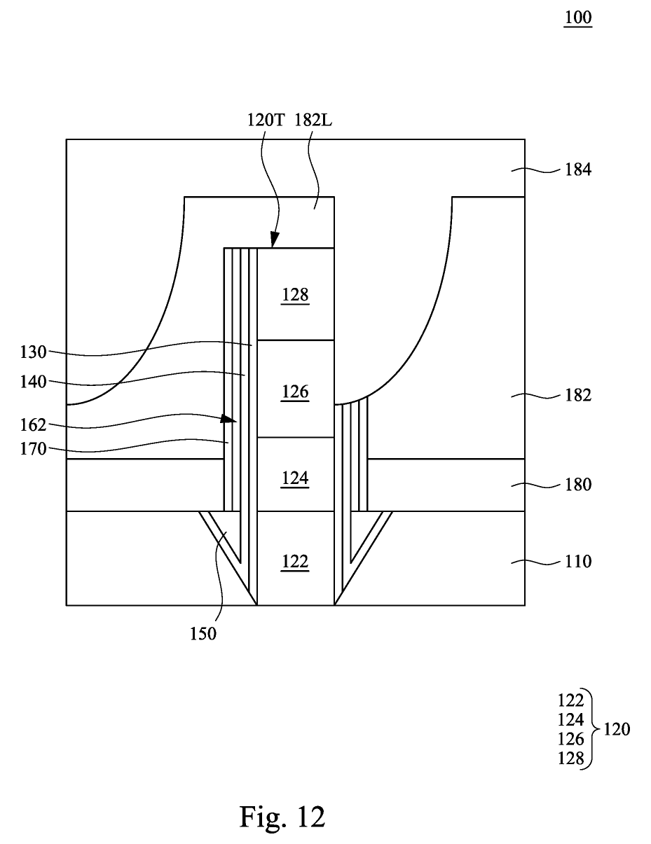

Referring to FIG. 11, a poly silicon layer 180 is formed on the substrate 110, and a tungsten layer 182 is formed on the poly silicon layer 180. In detail, the tungsten layer 182 may cover the top surface 120T of the bit line structure 120 and the tungsten layer 182 may seal the air gap 162. Referring to FIG. 12, a portion of the tungsten layer 182 is removed and an isolation layer 184 is formed on the tungsten layer 182. A landing pad 182L is then defined on the top surface 120T of the bit line structure. A portion of the first spacer 140 and the third spacer 170 is removed when defining the landing pad 182L. The air gap 162 is then re-sealed by the isolation layer 184. In some embodiments, the isolation layer 184 may include nitride, other dielectric materials or combinations thereof.

As shown in FIG. 1 to FIG. 12, the semiconductor structure 100 includes a substrate 110, a bit line structure 120, a seed layer 130, a first spacer 140, and an air gap 162. The substrate 110 has a recess 112, wherein the recess 112 has a sharp corner, and the recess has a maximum depth D1 near the bit line structure 120. The recess 112 has a vertical triangular cross-sectional profile. The bit line structure 120 is on the substrate 110 and the recess 112 surrounds the bit line structure 120. The seed layer 130 is located on the sidewall 120S of the bit line structure 120. A portion of the seed layer 130 is lower than the top surface 110T of the substrate 110. The first spacer 140 is located on the sidewall 130S of the seed layer 130 and on the bottom surface 112B of the recess 112. The second spacer 150 is filled in the recess 112, and the top surface 150T of the second spacer 150 is coplanar with the top surface 110T of the substrate 110. The third spacer 170 is located on the substrate 110 and on the top surface 150T of the second spacer 150. The third spacer is adjacent to the first spacer 140. The air gap 162 is between the first spacer 140 and the third spacer 170, wherein a bottom of the air gap exposes a portion of a top surface 150T of the second spacer150.

The semiconductor structure 100 includes a poly silicon layer 180, a tungsten layer 182, a landing pad 182L, and an isolation layer 184. The poly silicon layer 180 is on the top surface 110T of the substrate 110, and is contact with the third spacer 170. The tungsten layer 182 is on the poly silicon layer 180 and is over the top surface 120T of the bit line structure 120. The tungsten layer 182 is contact with the third spacer 170. The air gap 162 is sealed by the tungsten layer 182. A landing pad 182L is located on the top surface 120T of the bit line structure 120. The isolation layer 184 is on the tungsten layer 182, wherein the air gap 162 is sealed by the isolation layer 184. The isolation layer is contact with the sidewall 120S of the bit line structure 120.

The present disclosure provides a semiconductor structure and a manufacturing method thereof. With the method provided in this disclosure, the sacrificial spacer is removed to form the air gap between the first spacer and the third spacer. The seed layer can support the first spacer at the side nearing the bit line structure to maintain the thickness uniformity of the first spacer during air gap formation process. Moreover, the second spacer can support the first spacer at the bottom to reduce collapse during air gap formation process. Thus, the integrity of the air gap can be improved, and leakage and parasitic capacitance fail can be reduced. The air gap can effectively reduce the parasitic capacitance between the bit line and adjacent contact element, thereby increasing the stability of the semiconductor structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing semiconductor structure, comprising:
providing a bit line structure on a substrate, wherein a recess surrounds the bit line structure;
forming a seed layer, wherein a first portion of the seed layer is on a top surface of the bit line structure, a second portion of the seed layer is on a sidewall of the bit line structure, and a third portion of the seed layer is on a bottom surface of the recess;
removing the first portion of the seed layer and the third portion of the seed layer, such that the second portion of the seed layer is remained on the sidewall of the bit line structure;
forming a first spacer on the top surface of the bit line structure, a sidewall of the second portion of the seed layer, and the bottom surface of the recess;
forming a second spacer to fill the recess;
forming a sacrificial spacer on the top surface of the bit line structure and a sidewall of the first spacer;
forming a third spacer on the sacrificial spacer;
removing a portion of the third spacer and a portion of the sacrificial spacer to expose the top surface of the bit line structure; and
performing a vapor etching process to remove the sacrificial spacer, wherein an air gap is formed between the first spacer and the third spacer.

2. The method of claim 1, wherein the first spacer and the third spacer are made by the same material.

3. The method of claim 1, wherein the first spacer and the third spacer comprise nitride and hydrogen.

4. The method of claim 1, wherein the first spacer, the second spacer and the third spacer comprise nitride.

5. The method of claim 1, wherein the sacrificial spacer comprises oxide.

6. The method of claim 1, wherein the seed layer comprises silicon.

7. The method of claim 1, wherein a precursor for forming the seed layer comprising dichlorosilane (DCS).

8. The method of claim 1, further comprising:
after performing the vapor etching process, forming a poly silicon layer on the top surface of the substrate; and
forming a tungsten layer on the poly silicon layer and on the bit line structure, wherein the air gap is sealed by the tungsten layer.

9. The method of claim 8, further comprising:
removing a portion of the tungsten layer to define a landing pad on the top surface of the bit line structure.

10. The method of claim 9, further comprising:
after removing the portion of the tungsten layer, forming an isolation layer on the tungsten layer.

11. A semiconductor structure, comprising:
a substrate having a recess, wherein the recess has a sharp corner;
a bit line structure on the substrate, wherein the recess surrounds the bit line structure;
a seed layer located on a sidewall of the bit line structure;
a first spacer located on a sidewall of the seed layer and on a bottom surface of the recess;
a second spacer filled in the recess;
a third spacer located on the substrate and adjacent to the first spacer; and
an air gap between the first spacer and the third spacer, wherein a bottom of the air gap exposes a portion of a top surface of the second spacer.

12. The semiconductor structure of claim 11, wherein the bit line comprises:
a first conductive layer;
a second conductive layer on the first conductive layer;
a first hard mask layer on the second conductive layer; and
a second hard mask layer on the first hard mask layer.

13. The semiconductor structure of claim 11, wherein the top surface of the second spacer is coplanar with a top surface of the substrate.

14. The semiconductor structure of claim 11, further comprising:
a poly silicon layer on the substrate; and
a tungsten layer on the poly silicon layer and over the top surface of the bit line structure, wherein the air gap is sealed by the tungsten layer.

15. The semiconductor structure of claim 14, further comprising:
a landing pad on the top surface of the bit line structure; and
an isolation layer on the tungsten layer, wherein the air gap is sealed by the isolation layer and the tungsten layer.

16. The semiconductor structure of claim 11, wherein the recess has a maximum depth near the bit line structure.
